(19) United States
(12) Patent Application Publication
(10) Pub. No.: US 2026/0319458 A1
(43) Pub. Date: Oct. 15, 2026

(54) METHOD AND SYSTEM FOR DESIGNING A PHOTOMASK FOR CURVED SHAPE PATTERNING

(71) Applicant: GlobalFoundries U.S. Inc., Malta, NY (US)

(72) Inventors: Prashanth Raghavendra Prasad, Bangalore (IN); Surabhi Bhaskar, Mysore (IN); Ian P. Stobert, Hopewell Junction, NY (US); Venkatesh Mohanakrishnaswamy, Chennai (IN)

(21) Appl. No.: 19/173,891

(22) Filed: Apr. 9, 2025

(51) Int. Cl. G05B 19/4097

(52) U.S. Cl. CPC G05B 19/4097; G05B 2219/45028

(57) ABSTRACT

Methods and systems for designing a photomask include developing an initial photomask layout including a target photomask feature shape and a custom curvature control feature template for the target photomask feature shape. A photolithography process is simulated using the initial photomask layout to predict the shape of an unexposed area in a photosensitive layer resulting from the photolithography process. Overlaid outer boundaries of the target photomask feature shape and the predicted unexposed area shape are compared and, based on the results and on mask rules, the custom curvature control feature template is modified, thereby creating an intermediate photomask layout. Curvilinear model-based optical proximity correction (OPC), and curvature control assists printing avoidance are performed with respect to the intermediate photomask layout to develop a final photomask layout. By waiting until after the intermediate photomask layout has been developed to perform such processing, fewer OPC iterations can be employed with better results.

### BACKGROUND

The present disclosure relates to photolithography masks and, more particularly, to embodiments of methods and systems for designing a photolithography mask for curved shape patterning.

Photolithography techniques can employ a photomask to pattern shapes on a wafer. The photomask can include a base and one or more photomask features on the base. During an exposure process, light from a light source is directed through the photomask (e.g., in the case of a conventional photolithography technique) or reflected off the photomask (e.g., in the case of an extreme ultraviolet (EUV) photolithography technique) toward a photosensitive layer on the wafer. One of the challenges associated with these photolithography techniques is design and formation of the photomask so that, given inherent optical effects (e.g., light diffraction, etc.) that occur during the exposure process, an unexposed area of the photosensitive layer will have a target shape and size. This can be particularly difficult when the target shape for the unexposed area includes curve(s).

### SUMMARY

Embodiments disclosed herein include a computer-implemented method, a system and a computer program product for designing a photomask for curved shape lithographic patterning (e.g., for use in silicon photonics or any other technology including curved or otherwise non-linear components).

Disclosed embodiments of the method can include simulating a photolithography process. The photolithography process can be simulated by a processor using an initial photomask layout. The initial photomask layout can be stored in a memory accessible by the processor and can include a target photomask feature shape and a curvature control feature template for the target photomask feature shape. Simulation of the photolithography process can specifically be performed to predict an unexposed area shape in a photosensitive layer resulting from the photolithography process. The method can further include performing, by the processor, a comparison of overlaid outer boundaries of the target photomask feature shape and the predicted unexposed area shape and, based on results of the comparison, modifying, by the processor, the curvature control feature template to generate an intermediate photomask layout.

Disclosed embodiments of the system can include a memory and a processor. The memory can store program instructions for designing a photomask. The memory can further store an initial photomask layout. The initial photomask layout can include a target photomask feature shape and a curvature control feature template for the target photomask feature shape. The processor can be in communication with the memory such that the initial photomask layout and the program instructions are accessible by the processor. Additionally, the program instructions are executable by the processor to form a method. This method can include simulating a photolithography process using the initial photomask layout. Simulation of the photolithography process can specifically be performed to predict an unexposed area shape in a photosensitive layer resulting from the photolithography process. The method can further include performing a comparison of overlaid outer boundaries of the target photomask feature shape and the predicted unexposed area shape and, based on results of the comparison, modifying the curvature control feature template to generate an intermediate photomask layout.

Disclosed embodiments of the computer program product can include a non-transitory computer readable storage medium having program instructions embodied therewith. The program instructions can be executable by a processor to cause the processor to perform the above-described method.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a flow diagram illustrating disclosed embodiments of methods for designing, fabricating, and using a photomask;

FIG. 2.1-2.5 are drawings illustrating different processes, respectively, performed according to the flow diagram of FIG. 1;

FIG. 3 is a drawing illustrating overlaid boundaries of a target photomask feature shape and final photomask feature shape developed according to the flow diagram of FIG. 1;

FIG. 4.1-4.3 are different cross-section diagrams of a photomask formed according to final photomask layout developed according to the flow diagram of FIG. 1;

FIG. 5 is a schematic diagram illustrative of a hardware environment for implementing aspects of the disclosed systems, methods and computer program products; and

FIG. 6 is a drawing illustrating overlaid boundaries of a target photomask feature shape and final photomask feature shape developed according to prior art photomask design techniques.

### DETAILED DESCRIPTION

As mentioned above, one of the challenges associated with currently available photolithography techniques is design and formation of a photomask so that, given inherent optical effects (e.g., light diffraction, etc.) that occur during an exposure process, an unexposed area of a photosensitive layer on a wafer will have a target shape and size. This can be particularly difficult when the target shape for the unexposed area includes curve(s) (e.g., in the case of optical waveguides and other optical devices used in silicon photonics). Typically, the photomask design process includes drawing a target photomask feature shape for an initial photomask layout. The target photomask feature shape can have one or more curved (i.e., non-linear) edges and can correspond to the target unexposed area shape to be patterned into a photosensitive layer during a photolithography process. Curvilinear model-based optical proximity correction (OPC) can be performed based on the initial photomask layout. This curvilinear model-based OPC generates a final photomask feature shape, which is different from the target photomask feature shape and which is included in the final photomask layout in place of the target photomask feature shape. The curvilinear model-based OPC process is an iterative process during which the contours of the outer boundary of the final photomask feature shape are changed relative to the contours of the outer boundary of the target photomask feature shape to compensate for optical effects that are expected to occur during the photolithography process.

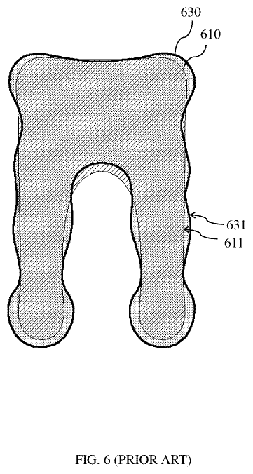

FIG. 6 is a diagram illustrating overlaid outer boundaries 611 and 631 of a target photomask feature shape 610 and a final photomask feature shape 630, respectively, that has been developed through curvilinear model-based OPC based on an initial photomask layout. To achieve the optimal final photomask feature shape 630, a significant number of OPC iterations is typically required (e.g., seven or more) resulting in a relatively long turn-around-time for photomask design. Additionally, as illustrated in FIG. 6, the final photomask feature shape 630 will typically be significantly different from the target photomask feature shape 610 and quite complex (e.g., including wavy as opposed to linear edges).

In view of the foregoing disclosed herein are embodiments of a method, system and computer program product for designing a photomask (also referred to herein as a photolithography mask or reticle) for curved shape lithographic patterning (e.g., for use in silicon photonics or any other technology including curved or otherwise non-linear components). In the disclosed embodiments, an initial photomask layout can be generated so that it includes a target photomask feature shape and a custom curvature control feature template for the target photomask feature shape. The custom curvature control feature template can include a sub-resolution assist feature (SRAF) portion and, depending upon the dimensions of the target photomask feature shape, a sub-resolution inverse feature (SRIF) portion. A photolithography process (e.g., a conventional or EUV photolithography process) can be simulated using this initial photomask layout (i.e., simulated as if performed with a photomask that has manufactured according to the initial photomask layout) in order to predict the resulting shape of an unexposed area in a photosensitive layer, which has been shadowed by the photomask during the photolithography process. A comparison of overlaid outer boundaries of the target photomask feature shape and the predicted unexposed area shape (also referred to herein as the predicted printed image shape) can be performed and, based on results of the comparison as well as on mask rules (e.g., critical widths for SRAF and SRIF elements), the custom curvature control feature template can be modified (e.g., trimmed) to generate an intermediate photomask layout. Curvilinear model-based OPC as well as curvature control assists (CCA) printing avoidance can be performed with respect to the intermediate photomask layout in order to generate a final photomask layout (including a final photomask feature shape and final curvature control feature shapes). By waiting until after the intermediate photomask layout (including the final curvature control feature shapes) has been generated to perform such processing and, particularly, to perform iterative curvilinear model-based OPC processing, better results can be achieved (e.g., the final photomask feature shape can have curves and linear edges more closely resembling the target photomask feature shape) using a relatively small number of OPC iterations (e.g., five or less) for a faster turn-around-time.

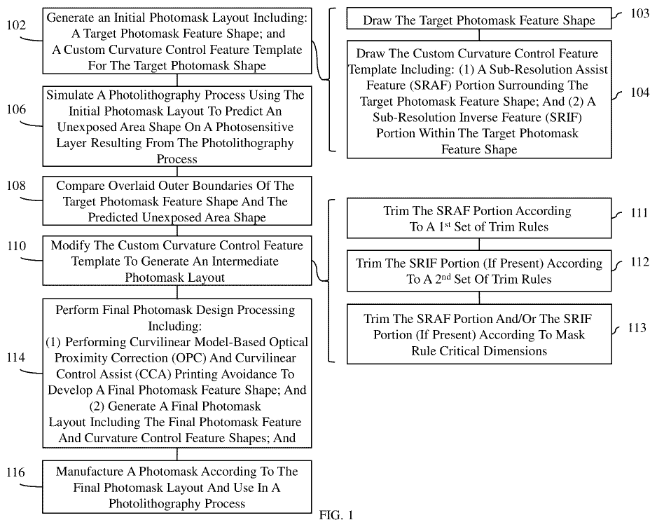

More particularly, FIG. 1 is a flow diagram illustrating disclosed embodiments of methods for designing, fabricating, and using a photomask. It should be noted that these method embodiments can, at least in part, be computer-implemented. That is, one or more of the processes described below and illustrated in the flow diagram of FIG. 1 can be performed by a processor of a computer system through execution of program instructions, which are stored on a computer readable storage medium (or media) and which are readable by the processor.

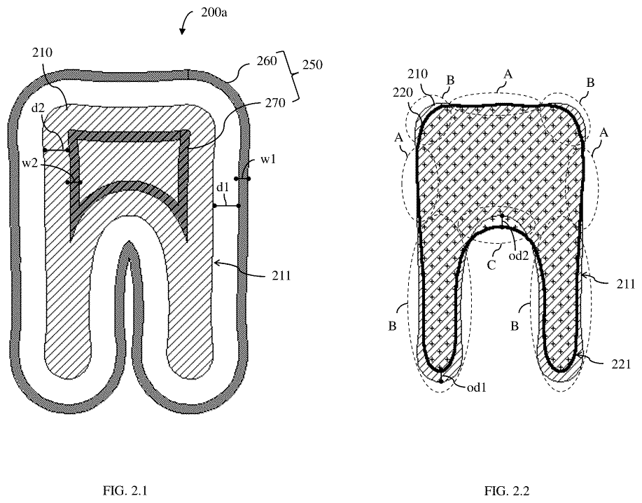

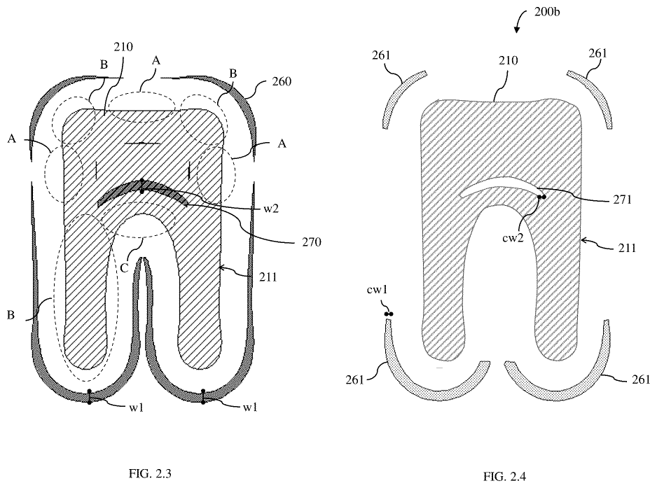

The method can include generating an initial photomask layout 200a (including a target photomask feature shape 210 and a custom curvature control feature template 250 for target photomask feature shape 210) and storing the initial photomask layout 200a in memory (e.g., see process 102 and FIG. 2.1). Specifically, target photomask feature shape 210 can be drawn based on a target shape and size for an unexposed area (i.e., a shadowed area) to be patterned into a photosensitive layer on a semiconductor wafer during an exposure step of a photolithography process (see process 103). The target shape of the unexposed area and, thereby the target photomask feature shape 210 can include one or more curves. It should be noted that the target photomask feature shape 210 shown in FIG. 2.1 (which has multiple curves in its outer boundary 211 and which has different portions with different width dimensions) is provided for illustration purposes and is not intended to be limiting. Alternatively, the target shape of the unexposed area and, thereby the target photomask feature shape could include any number of one or more curves in its outer boundary and could further have, for example: an essentially uniform width dimension or any number of two or more different width dimensions.

Once the target photomask feature shape 210 is drawn, a custom curvature control feature template 250 can be drawn for the target photomask feature shape 210, according to a set of predefined rules for curvature control feature template generation (hereinafter referred to as the template rules) (see process 104). It should be understood that these template rules will follow known edge placement error (EPE) criterion.

The custom curvature control feature template 250 can be drawn at process 104 and according to the template rules so that it includes a sub-resolution assist feature (SRAF) portion 260. Those skilled in the art will recognize that an SRAF is a material element that can be formed on a photomask adjacent to a photomask feature shape. The SRAF will have a sub-resolution width dimension (i.e., a width dimension that is sufficiently small to ensure that the image of the SRAF will not be transferred into the photosensitive layer during the exposure process) and will be placed adjacent to the photomask feature shape so as to alter optical effects that are expected to occur during the photolithography process and thereby improve the results. Generally, SRAF portion 260 can be drawn so as to be similar in shape to (but larger in size than, i.e., upsized relative to) target photomask feature shape 210. For example, SRAF portion 260 can be drawn as a continuous shape that: (1) laterally and completely surrounds target photomask feature shape 210; (2) is separated from the outer boundary by no less than a first distance (d1); (3) conformally follows and is adjacent to the outer boundary 211 of target photomask feature shape 210; and (4) has a first width (w1), which is essentially uniform. It should be noted that SRAF portion 260 ideally conformally follows the entire outer boundary 211 of target photomask feature shape 210 and is separated therefrom by first distance (d1) (as illustrated in FIG. 2.1). However, if the target photomask feature shape 210 has a U-shape, an S-shape, or otherwise has side-by-side segments and those side-by-side segments are relatively close to each other, it may be impossible, due to lack of available space, for SRAF portion 260 to have a uniform first width (d1) and to follow the contour of the entire outer boundary 211 (including between the side-by-side segments) and/or for SRAF portion 260 to be separated from outer boundary 211 by the first distance (d1) (including between the side-by-side segments). For these or similar cases, the template rules may dictate that the narrow space between the side-by-side segments should be devoid of SRAF portion 260 or that this narrow space will include only a single branch of SRAF portion 260.

In some cases, the custom curvature control feature template 250 can also be drawn at process 104 and according to the template rules so that it includes a sub-resolution inverse feature (SRIF) portion 270. Those skilled in the art will recognize that an SRIF is an opening formed within a photomask feature shape on a photomask. The SRIF will have a sub-resolution width dimension (i.e., a width dimension that is sufficiently small to ensure that the image of the SRAF will not be transferred into the photosensitive layer during the exposure process) and will be formed within the photomask feature shape so as to alter optical effects that are expected to occur during the photolithography process and thereby improve the results. Generally, SRIF portion 270 can be drawn so as to be similar in shape to (but smaller in size than, i.e., downsized relative to) target photomask feature shape 210. For example, SRIF portion 270 can be drawn so that it: (1) is within and adjacent to the outer boundary 211 of the target photomask feature shape 210; (2) is separated from outer boundary 211 by no less than a second distance (d2), which is the same as or different from the first distance (d1) mentioned above; (3) at least partially follows the contour of the outer boundary 211; and (4) has a second width (w2), which is essentially uniform and which is the same as or different from the first width (w1) mentioned above. The template rules may specify that SRIF portion 270 can be continuous, following the contour of the entire outer boundary 211 of the target photomask feature shape 210 if the target photomask feature shape 210 is relatively wide throughout (i.e., if the minimum width of the target photomask feature shape 210 is greater than some predetermined width). The template rules may also specify that no SRIF portion 270 is warranted, if target photomask feature shape 210 is relatively narrow throughout (i.e., if the maximum width of the target photomask feature shape 210 is less than some predetermined width). The template rules may also specify that if the target photomask feature shape 210 has relatively narrow and wide segments, the wide segment(s) may include an SRIF portion 270 (e.g., conformally following the outer boundary only within the wide segment(s)) and the narrow section(s) may be devoid of SRIF portion 270 (as illustrated in FIG. 2.1). As mentioned above, in the disclosed embodiments template rules for creating the custom curvature control feature template will follow known EPE criteria. Thus, the example template rules set forth above and related to creation of the SRAF portion 260 and SRIF portion 270 of the template 250 are provided for illustration purposes and are not intended to be limiting. For example, depending upon the EPE criteria, template rules may, alternatively, provide for the creation of SRIF features even when a target photomask feature shape or portion thereof is relatively narrow.

In any case, drawing of target photomask feature shape 210 (process 103) and further drawing of custom curvature control feature template 250 (process 104) can be performed using any suitable drawing technique. For example, they could be: hand drawn (e.g., with pen or pencil on paper), scanned-in, and saved in memory; hand drawn using a digital drawing tool and saved in memory; or automatically generated by a digital drawing tool and saved in memory. In any case, a combined drawing of the target photomask feature shape 210 and custom curvature control feature template 250 can placed within an initial photomask layout 200a at a desired location.

The method can further include simulating a photolithography process using the initial photomask layout 200a generated at process 102 (see process 106 and FIG. 2.2). The simulation process can specifically be performed in order to predict an unexposed area shape 220 (i.e., the shape of an unexposed area, also referred to herein as the predicted unexposed area shape or printed image shape) in a photosensitive layer resulting from the photolithography process. The method can also include performing, by the processor, a comparison of overlaid outer boundaries 211 and 221 of target photomask feature shape 210 and predicted unexposed area shape 220, respectively (see process 108 and FIG. 2.2). This comparison can be performed to identify: any first areas (A) where the overlaid outer boundaries 211, 221 are aligned; any second areas (B) where outer boundary 221 is within outer boundary 211; and any third areas (C) where outer boundary 221 is outside outer boundary 211. This comparison can also be made to map the separation distances between the overlaid outer boundaries 211 and 221 in the second areas (B) and third areas (C). Results of the comparison can be stored in memory.

The method can further include modifying curvature control feature template 250 (including SRAF portion 260 and, if applicable, SRIF portion 270) to generate an intermediate photomask layout 200b and storing the intermediate photomask layout 200b in memory (see process 110 and FIGS. 2.2-2.4).

Modifying the curvature control feature template 250 can include trimming SRAF portion 260 based on the results of the comparison of the overlaid outer boundaries 211 and 221 and according to a first set of trim rules (see process 111, see FIGS. 2.2-2.3). Trimming of SRAF portion 260 can include removing any section of SRAF portion 260 adjacent to where outer boundary 221 of predicted unexposed area shape 220 is aligned with outer boundary 211 of target photomask feature shape 210 (e.g., in first areas (A)) or outside outer boundary 211 of target photomask feature shape 210 (e.g., in third areas (C)). Trimming of SRAF portion 260 can also include thinning any section of SRAF portion 260 adjacent to where outer boundary 221 of predicted unexposed area shape 220 is inside outer boundary 211 of target photomask feature shape 210 but separated therefrom by less than a first offset distance (od1). As illustrated, the amount of thinning can be reduced as the distance between outer boundaries 211 and 221 increases toward the first offset distance (od1). Additionally, at process 111, any section of SRAF portion 260 adjacent to where outer boundary 221 of predicted unexposed area shape 220 is inside outer boundary 211 of target photomask feature shape 210 and separated therefrom by at least the first offset distance (od1) can be left intact.

Modifying the curvature control feature template 250 can further include trimming SRIF portion 270, if present, based on the results of the comparison of the overlaid outer boundaries 211 and 221 and according to a second set of trim rules (see process 112 and FIGS. 2.2-2.3). Trimming of SRIF portion 270 can include removing any section of SRIF portion 270 adjacent to where outer boundary 221 of predicted unexposed area shape 220 is inside outer boundary 211 of target photomask feature shape 210 (e.g., in second areas (B)). Trimming of SRIF portion 270 can include thinning any section of SRIF portion 270 adjacent to where outer boundary 221 of predicted unexposed area shape 220 is aligned with outer boundary 211 of target photomask feature shape 210 or outside outer boundary 211 of target photomask feature shape 210 and separated therefrom by less than a second offset distance (od2). As illustrated, the amount of thinning can be reduced as the distance between outer boundaries 211 and 221 increases toward the second offset distance (od2). Additionally, at process 112, any section of SRIF portion 270 adjacent to where outer boundary 221 of predicted unexposed area shape 220 is outside outer boundary 211 of target photomask feature shape 210 and separated therefrom by at least the second offset distance (od2).

Modifying the curvature control feature template 250 can further include further trimming SRAF portion 260 and, if present, SRIF portion 270, to meet SRAF and SRIF critical widths (see process 113, see FIG. 2.4). That is, variations in the width of SRAF portion 260 and variations in the width of SRIF portion 270 (if present) can be mapped. Any previously trimmed sections and, more particularly, any previously thinned sections of SRAF portion 260 that have a width that is less than a first critical width (cw1) (e.g., as specified in mask rules and determined during mask rule checking) can be removed. Any previously trimmed sections and, more particularly, any previously thinned sections of SRIF portion 260 that have a width that is less than a second critical width (cw2) (e.g., as specified in mask rules and determined during mask rule checking) can be removed. It should be noted that this second critical width (cw2) may be the same as or different from the first critical width (cw1) mentioned above.

In any case, modifying the curvature control feature template 250 as described above results in an intermediate photomask layout 200b including final curvature control feature shapes. The final curvature control feature shapes can include one or more final SRAF shapes 261 adjacent to target photomask feature shape 210 and, potentially, one or more final SRIF shapes 271 within target photomask feature shape 210.

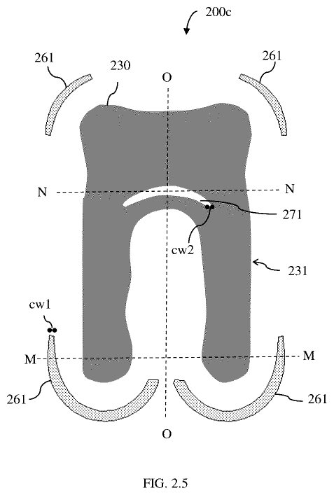

The method can further include performing final photomask design processing to generate and store, in memory, a final photomask layout 200c (see process 114 and FIG. 2.5). Final photomask design processing can include performing curvilinear model-based OPC correction and further performing curvature control assists (CCA) printing avoidance using the intermediate photomask layout 200b (including final curvature control feature shapes 261 and 271, if applicable) in order to develop a final photomask feature shape 230. The final photomask layout 200c can then be generated so as to include both final photomask feature shape 230 and the final curvature control feature shapes 261 and 271, if applicable. In combination, the curvilinear model-based OPC and CCA printing avoidance processes are iterative, during which the contours of the outer boundary 231 of final photomask feature shape are changed relative to the contours of the outer boundary 211 of target photomask feature shape 210 to compensate for optical effects that are expected to occur during the photolithography process (given inclusion in the photomask of, not just the photomask feature shape, but also the final curvature control feature shapes 261, 271). FIG. 3 illustrates overlaid boundaries 211 and 231 of target photomask feature shape 210 and final photomask feature shape 230. It should be noted that the final photomask feature shape 230 shown in FIG. 3 has curves and linear edges more closely resembling those in target photomask feature shape 210 (as compared to the final photomask feature shape 630 and target photomask feature shape 610 shown in FIG. 6 and discussed above). For example, as illustrated by the overlaid boundaries 211 and 231 in FIG. 3, the final photomask feature shape 230 and the target photomask feature shape 210 have curves with approximately equal arc lengths and approximately equal angles of curvature and further have linear edges that are approximately aligned. Thus, by waiting until after the intermediate photomask layout 200b (including the final curvature control feature shapes 261 and 271, if applicable) has been generated to perform such processing and, particularly, to perform iterative curvilinear model-based OPC processing, better results can be achieved. Furthermore, these results can be achieved using a relatively small number of OPC iterations (e.g., five or less) for a faster turn-around-time.

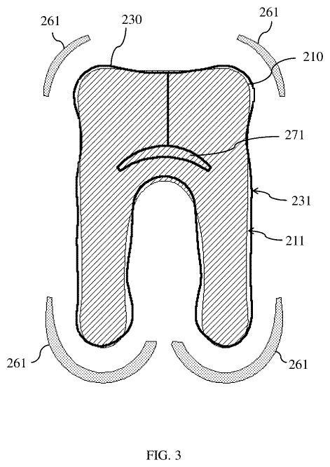

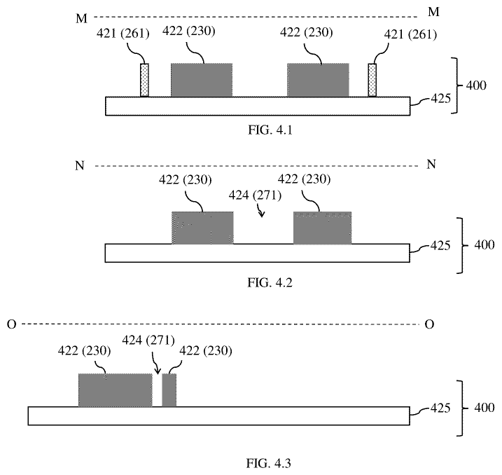

The method can further include manufacturing a photomask 400 based on the final photomask layout 200c (see process 116). FIGS. 4.1-4.3 are different cross-section diagrams of a photomask 400 formed according to final photomask layout 200c. Photomask 400 can include a base 425 and a photomask feature 422 on base 425. Photomask feature 422 can correspond to the final photomask feature shape 230 in final photomask layout 200c and can include a narrow opening 424 extending therethrough and corresponding to SRIF shape 271 in final photomask layout 200c. Photomask 400 can further include SRAFs 421 on base 425 adjacent to photomask feature 422 and corresponding to SRAF shapes 261 in final photomask layout 200c. Photomask feature 422 and SRAFs 421 can, for example, be patterned from the same material(s) and can have the same height as measured from a top surface of base 425. Those skilled in the art will recognize that the various materials employed for photomask 400 can vary depending upon the type of photolithography. For example, for conventional photolithography, base 425 can be made of a transparent material, such as glass, and photomask feature 422 and SRAFs 421 can be made of an opaque material layer, such as a chrome layer. For EUV photolithography, base 425 can include 40-50 alternating spacer layers and reflector layers (e.g., silicon-based glass spacer layers and molybdenum reflector layers) and photomask feature 422 and SRAFs 421 can be made of an absorber material layer, such as a tantalum or tantalum alloy layer.

Once the photomask 400 is manufactured, it can be used during a photolithography process to pattern shapes on a wafer. Specifically, during an exposure process light from a light source is directed through the photomask (e.g., in the case of a photomask designed for conventional photolithography) or reflected off the photomask (e.g., in the case of a photomask designed for extreme ultraviolet (EUV) photolithography) toward a photosensitive layer on the wafer. Optionally, during this exposure process the light can pass through one or more lenses (e.g., of an illumination unit) before reaching the photomask and/or the light can pass through one or more lenses (e.g., of a projection unit) before reaching the photosensitive layer. In any case, due to the shapes of the photomask feature(s) on the photomask, one or more areas of the photosensitive layer will be exposed to the light and one or more areas will remain unexposed (i.e., in shadows due to the pattern of the photomask feature(s) on the photomask). Depending upon whether the photosensitive layer is a positive or negative photosensitive material, the exposed area(s) will become soluble to a particular solvent and the unexposed area(s) will remain insoluble or vice versa. In any case, when the photosensitive layer is subsequently developed (i.e., placed in the particular solvent), the soluble area(s) will be washed away (i.e., removed) and the insoluble area(s) will remain intact, thereby forming patterned opening(s) in the photosensitive layer. Etch processes can then be performed to extend the patterned opening(s) into a layer below (e.g., to form curved or otherwise non-linear component(s), such as an optical waveguide or other optical device employed in silicon photonics).

The embodiments disclosed herein may be implemented as a method (e.g., a computer-implemented method, as described above), a system (e.g., a computer-aided design system), and/or a computer program product. Each computer program product may include a computer readable storage medium (or media) having computer readable program instructions thereon for causing a processor to carry out aspects of the disclosed embodiments. A computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the disclosed embodiments may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the disclosed embodiments.

Aspects of the disclosed embodiments are described herein with reference to flowchart illustrations and/or block diagrams of methods, apparatus (systems), and computer program products according to disclosed embodiments. It will be understood that each block of the flowchart illustrations and/or block diagrams, and combinations of blocks in the flowchart illustrations and/or block diagrams, can be implemented by computer readable program instructions. These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the figures illustrate the architecture, functionality, and operation of possible implementations of systems, methods, and computer program products according to various disclosed embodiments. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

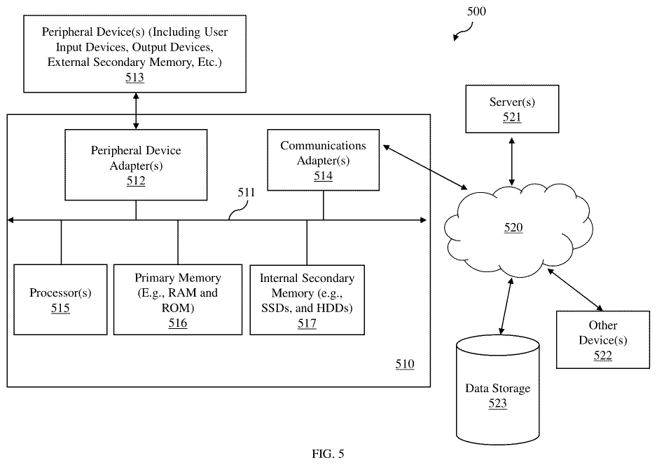

An exemplary hardware environment 500 for implementing aspects of the disclosed systems, methods and computer program products is depicted in FIG. 5. Generally, the hardware environment can include at least one computing device 510 (also referred to herein as a computer). Computer 510 can be, for example, a desktop, laptop, tablet, mobile computing device, etc. Computer 510 can include at least one bus 511. Bus 511 can be connected to various other components of computer 510 and can be configured to facilitate communication between those components.

Computer 510 can include various adapters. The adapters can include one or more peripheral device adapters 512, which are configured to facilitate communications between one or more peripheral devices 513, respectively, and bus 511. Peripheral devices 513 can include user input devices configured to receive user inputs. User input devices can include, but are not limited to, a keyboard, a mouse, a microphone, a touchpad, a touchscreen, a stylus, bio-sensor, a scanner, or any other type of user input device. Peripheral devices 513 can also include additional input devices, such as external secondary memory devices (as discussed in greater detail below). Peripheral devices 513 can also include output devices. The output devices can include, but are not limited to, a printer, a monitor, a speaker, or any other type of computer output device. The adapters can include one or more communications adapters 514 (also referred to herein as a computer network adapters), which are configured to facilitate communications between computer 510 and one or more communications networks 520 (e.g., a wide area network (WAN), a local area network (LAN), the internet, a cellular network, a Wi-Fi network, etc.). Such network(s) 520 can, in turn, facilitate communications between computer 510 and other system components on the network: remote server(s) 521, other device(s) 522 (e.g., computers, laptops, tablets, mobile phones, etc.), remote data storage 523, etc.

Computer 510 can further include at least one processor 515 (also referred to herein as a central processing units (CPU)). Optionally, each CPU 515 can include a CPU cache. Each CPU 515 can be configured to read and execute program instructions.

Computer 510 can further include memory and, particularly, computer-readable storage mediums. The memory can include primary memory 516 and secondary memory. Primary memory 516 can include, but is not limited to, random access memory (RAM) (e.g., volatile memory employed during execution of program operations) and read only memory (ROM) (e.g., non-volatile memory employed during start-up). The RAM can include, but is not limited to, dynamic random access memory (DRAM), static random access memory (SRAM), or any other suitable type of RAM. The ROM can include, but is not limited to, erasable programmable read only memory (EPROM), flash memory, electronically erasable programmable read only memory (EEPROM), programmable read only memory (PROM), or any other suitable type of ROM. The secondary memory can be non-volatile. The secondary memory can include internal secondary memory 517, such as internal solid state drive(s) (SSD(s)) and/or internal hard disk drive(s) (HDD(s), installed within computer 510 and connected to bus 511. The secondary memory can also include external secondary memory connected to or otherwise in communication with the computer 510 (e.g., peripheral devices). The external secondary memory can include, for example, external/portable SSD(s), external/portable HDD(s), flash drive(s), thumb drives, compact disc(s) (CD(s)), digital video disc(s) (DVD(s)), network-attached storage (NAS), storage area network (SAN), or any other suitable non-transitory computer-readable storage media connected to or otherwise in communication with computer 510. The different functions of primary and secondary memory are well known in the art and, thus, the details thereof have been omitted from this specification in order to allow the reader to focus on the salient aspects of the disclosed embodiments.

In some embodiments, program instructions for performing the disclosed method or a portion thereof, as described above, can be embodied in (e.g., stored in) secondary memory accessible by computer 510. When the program instructions are to be executed (e.g., in response to user inputs to computer 510), required information (e.g., the program instructions and other data) can be loaded into the primary memory (e.g., stored in RAM). CPU 515 can read the program instructions and other data from the RAM and can execute the program instructions. In other embodiments, a client-server model can be employed. In this case, computer 510 can be a client and a remote server 521 in communication with computer 510 over a network 520 can provide, to the client, a service including execution of program instructions for performing the disclosed method or a portion thereof, as described above, in response to user inputs to computer 510.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
simulating, by a processor, a photolithography process using an initial photomask layout, wherein the initial photomask layout is stored in a memory accessible by the processor and includes a target photomask feature shape and a curvature control feature template for the target photomask feature shape, and wherein the simulating predicts an unexposed area shape in a photosensitive layer resulting from the photolithography process;
performing, by the processor, a comparison of overlaid outer boundaries of the target photomask feature shape and the predicted unexposed area shape; and
based on results of the comparison, modifying, by the processor, the curvature control feature template to generate an intermediate photomask layout.

2. The method of claim 1, further comprising generating the initial photomask layout such that the curvature control feature template includes a sub-resolution assist feature portion surrounding the target photomask feature shape.

3. The method of claim 2, wherein the sub-resolution assist feature portion is separated from an outer boundary of the target photomask feature shape by a first distance, at least partially follows a contour of the outer boundary of the target photomask feature shape, has a continuous shape, and has a first width.

4. The method of claim 3, wherein the modifying of the curvature control feature template includes:
removing any section of the sub-resolution assist feature portion adjacent to where an outer boundary of the predicted unexposed area shape is aligned with or outside the outer boundary of the target photomask feature shape;
thinning any section of the sub-resolution assist feature portion adjacent to where the outer boundary of the predicted unexposed area shape is inside the outer boundary of the target photomask feature shape and separated therefrom by less than a first offset distance; and
leaving intact any section of the sub-resolution assist feature portion adjacent to where the outer boundary of the predicted unexposed area shape is inside the outer boundary of the target photomask feature shape and separated therefrom by at least the first offset distance.

5. The method of claim 4, wherein the generating of the initial photomask layout is performed such that the curvature control feature template includes a sub-resolution inverse feature portion within the target photomask feature shape.

6. The method of claim 5,
wherein the sub-resolution inverse feature portion is separated from the outer boundary of the target photomask feature shape by a second distance, at least partially follows a contour of the outer boundary of the target photomask feature shape, and has a second width, and
wherein the modifying of the curvature control feature template further includes:
removing any section of the sub-resolution inverse feature portion adjacent to where the outer boundary of the predicted unexposed area shape is inside the outer boundary of the target photomask feature shape;
thinning any section of the sub-resolution inverse feature portion adjacent to where the outer boundary of the predicted unexposed area shape is outside the outer boundary of the target photomask feature shape and separated therefrom by less than a second offset distance; and
leaving intact any section of the sub-resolution inverse feature portion adjacent to where the outer boundary of the predicted unexposed area shape is outside the outer boundary of the target photomask feature shape and separated therefrom by at least the second offset distance.

7. The method of claim 6, wherein the modifying of the curvature control feature template further includes removing any trimmed section of the curvature control feature template having a width below a critical width to develop final curvature control feature shapes.

8. The method of claim 1, further comprising:
performing, by the processor, curvilinear model-based optical proximity correction and curvature control assists printing avoidance using the intermediate photomask layout to develop a final photomask feature shape; and
generating, by the processor, a final photomask layout including the final photomask feature shape and the final curvature control feature shapes.

9. The method of claim 8, wherein the final photomask feature shape and the target photomask feature shape have curves with approximately equal arc lengths and approximately equal angles of curvature.

10. The method of claim 8, further comprising manufacturing a photomask based on the final photomask layout.

11. A system comprising:
a memory storing program instructions and an initial photomask layout, wherein the initial photomask layout includes a target photomask feature shape and a curvature control feature template for the target photomask feature shape; and
a processor in communication with the memory, wherein the program instructions are executable by the processor to perform a method including:
simulating a photolithography process using the initial photomask layout, wherein the simulating is performed to predict an unexposed area shape in a photosensitive layer resulting from the photolithography process;
performing a comparison of overlaid outer boundaries of the target photomask feature shape and the predicted unexposed area shape; and
based on results of the comparison, modifying the curvature control feature template to generate an intermediate photomask layout.

12. The system of claim 11, wherein the method further includes generating the initial photomask layout such that the curvature control feature template includes a sub-resolution assist feature surrounding the target photomask feature shape.

13. The system of claim 12, wherein the sub-resolution assist feature portion is separated from an outer boundary of the target photomask feature shape by a first distance, at least partially follows a contour of the outer boundary of the target photomask feature shape, has a continuous shape, and has a first width.

14. The system of claim 13, wherein the modifying of the curvature control feature template includes:
removing any section of the sub-resolution assist feature portion adjacent to where an outer boundary of the predicted unexposed area shape is aligned with or outside the outer boundary of the target photomask feature shape;
thinning any section of the sub-resolution assist feature portion adjacent to where the outer boundary of the predicted unexposed area shape is inside the outer boundary of the target photomask feature shape and separated therefrom by less than a first offset distance; and
leaving intact any section of the sub-resolution assist feature portion adjacent to where the outer boundary of the predicted unexposed area shape is inside the outer boundary of the target photomask feature shape and separated therefrom by at least the first offset distance.

15. The system of claim 11, wherein the generating of the initial photomask layout is performed such that the curvature control feature template includes a sub-resolution inverse feature portion within the target photomask feature shape.

16. The system of claim 15,
wherein the sub-resolution inverse feature portion is separated from the outer boundary of the target photomask feature shape by a second distance, at least partially follows a contour of the outer boundary of the target photomask feature shape, and has a second width, and
wherein the modifying of the curvature control feature template further includes:
removing any section of the sub-resolution inverse feature portion adjacent to where the outer boundary of the predicted unexposed area shape is inside the outer boundary of the target photomask feature shape;
thinning any section of the sub-resolution inverse feature portion adjacent to where the outer boundary of the predicted unexposed area shape is outside the outer boundary of the target photomask feature shape and separated therefrom by less than a second offset distance; and
leaving intact any section of the sub-resolution inverse feature portion adjacent to where the outer boundary of the predicted unexposed area shape is outside the outer boundary of the target photomask feature shape and separated therefrom by at least the second offset distance.

17. The system of claim 16, wherein the modifying further includes removing any section of the curvature control feature template having a width below a critical width to develop final curvature control feature shapes.

18. The system of claim 11, wherein the method further includes:
using the intermediate photomask layout, performing curvilinear model-based optical proximity correction and curvature control assists printing avoidance to develop a final photomask feature shape;
generating a final photomask layout including the final photomask feature shape and the final curvature control feature shapes; and
manufacturing a photomask based on the final photomask layout.

19. The system of claim 18, wherein the final photomask feature shape and the target photomask feature shape have curves with approximately equal arc lengths and approximately equal angles of curvature.

20. A computer program product comprising a non-transitory computer readable storage medium having program instructions embodied therewith, wherein the program instructions is executable by a processor to cause the processor to perform a method including:
simulating a photolithography process using an initial photomask layout, wherein the initial photomask layout includes a target photomask feature shape and a curvature control feature template adjacent to the target photomask feature shape, and wherein the simulating predicts an unexposed area shape in a photosensitive layer resulting from the photolithography process;
performing a comparison of overlaid outer boundaries of the target photomask feature shape and the predicted unexposed area shape; and
based on results of the comparison, modifying the curvature control feature template to generate an intermediate photomask layout.
